(19) United States
(12) Patent Application Publication
(10) Pub. No.: US 2010/0109038 A1
(43) Pub. Date: May 6, 2010

(54) LIGHT EMITTING DIODE WITH INTEGRAL PARABOLIC REFLECTOR

(75) Inventors: Jerry Moore, Boulder, CO (US); Christian J. Moore, Boulder, CO (US)

Correspondence Address: PATTON BOGGS LLP, 1801 CALFORNIA STREET, SUITE 4900, DENVER, CO, 80202, US

(73) Assignee: Playhard, Inc., Boulder, CO (US)

(21) Appl. No.: 12/624,180

(22) Filed: Nov. 23, 2009

Related U.S. Application Data
(62) Division of application No. 11/486,921, filed on Jul. 14, 2006, now abandoned.
(60) Provisional application No. 60/699,153, filed on Jul. 14, 2005.

(51) Int. Cl. H01L 33/00

(52) U.S. Cl. 257/98; 257/E33.067

(57) ABSTRACT

The dielectric casing of a light emitting diode (LED) incorporates an integral parabolic reflector system which redirects light in a collimated pattern deflected at significant angles relative to the axis of symmetry of the LED.

### CROSS-REFERENCE TO RELATED APPLICATIONS

This application is a divisional of U.S. patent application Ser. No. 11/486,921 filed Jul. 14, 2006, which claims the benefit of U.S. Provisional Patent Application 60/699,153 filed on Jul. 14, 2005. The foregoing non-provisional and provisional applications are hereby incorporated by reference to the same extent as though fully disclosed herein.

### FIELD OF THE INVENTION

This invention relates in general to light emitting diodes (LEDs), and more particularly to apparatus and methods for directing the light emitted from the LED.

### BACKGROUND OF THE INVENTION

The efficiency, reliability, and compact size of LEDs makes them increasingly attractive for use in lighting devices of all kinds. However, because the semiconductor die forming the heart of an LED is essentially a point source of light, LEDs inherently produce light that radiates in all directions. Thus, a problem with LEDs is that the light emitted cannot be directed as precisely as that in other optical systems without losing the essential compactness and simplicity of the LED.

A number of inventors have attempted to develop or improve systems for concentrating or diffusing this multi-directional radiation in specific patterns useful for particular applications. One approach is to mold the exterior surface of the dielectric casing which houses the semiconductor die in the form of a convex or concave lens. This method provides a means of transmitting a light emitted from the semiconductor die through the lens surface in a roughly conical beam collinear with the axis of the LED. U.S. Pat. No. 5,865,529 granted Feb. 2, 1999 to Ellis Yan discloses such a device for diffusing light in a 360° viewing plane in both horizontal and vertical axes. However, this method cannot focus the dominant portion of emitted light at an angle substantially away (i.e., >45°) from the symmetric axis of the LED and lens while simultaneously excluding radiation at shallower angles to the symmetric axis (i.e., <45°).

Another approach is to provide a silvered or refractive reflector mechanically separate from the LED which is aligned to intercept light radiated along the axis of the LED and reflect it in a pattern suitable for the particular application. Unlike the lens method, this approach allows for deflection of the dominate portion of the emitted light at significant angles away from the symmetric axis of the LED while excluding radiation at shallower angles. U.S. Pat. No. 5,769,532 granted Jun. 23, 1998 to H. Sasaki, U.S. Pat. No. 6,364,506 B1 granted Apr. 2, 2002 to M. Gallo, U.S. Pat. No. 6,447,155 B2 granted Sep. 10, 2002 to T. Kondo and H. Okada, and U.S. Pat. No. 6,846,101 B2 granted Jan. 25, 2005 to C. Coushaine all disclose devices employing such a mechanically separate reflector to redirect light from an LED. However, the mechanical arrangement of the LED and separate reflector increases the complexity, space required, alignment difficulty, and cost for this assembly.

A third approach is to mold the exterior surface of the dielectric casing of the LED in the form of a concave cone of faceted planes or approximating curves which, by means of total internal reflection, redirects light emitted by the LED die away from the axis of the LED. These methods allow diffusion of light at substantial angles from the axis of the LED. U.S. Pat. No. 3,774,021 granted Nov. 20, 1973 to B. Johnson and U.S. Pat. No. 6,488,392 B1 granted Dec. 3, 2002 to C. Lu both disclose devices using convex planar or curved surfaces to randomly diffuse light emitted from a semiconductor die in a roughly radial direction away from the symmetric axis of the LED. However, neither method produces a uniform dispersion of the reflected light consisting of parallel rays oriented at a precise angle relative to the symmetrical axis of the LED.

None of these existing approaches provide an apparatus and method of maintaining precise control over the direction of light emitted by the LED rays while at the same time retaining the primary desirable characteristics of an LED, namely, simplicity and compactness.

### BRIEF SUMMARY OF THE INVENTION

The invention provides an LED that synergistically retains the simplicity and compactness of an LED in a light source in which the direction of the emitted light can be precisely controlled. The invention provides the economy of an integral reflector with geometry that produces reflected rays uniformly and precisely oriented at larger angles away from the LED's axis of symmetry.

The invention provides a light emitting diode (LED) assembly comprising: a dielectric casing of optically transparent material; first and second electrical leads extending within the dielectric casing; and at least one semiconductor die embedded in the dielectric casing and coupled to the first and second leads in a manner allowing for transfer of electrical energy to and illumination of the at least one semiconductor die; and, wherein the dielectric casing has a surface, at least a portion of which is parabolic, the parabolic surface portion located and dimensioned for reflecting light emitted by the at least one semiconductor die. Preferably, the dielectric casing has a plurality of the parabolic surface portions. Preferably, the parabolic surfaces are located and dimensioned to reflect light emitted by the at least one semiconductor die into a plurality of beams. Preferably, the parabolic surface portion defines a parabolic curve rotated around the axis of the LED. Preferably, the parabolic surface portion defines a parabolic curve rotated around an axis through the LED and perpendicular to the axis of the LED. Preferably, the parabolic surface portion is located and dimensioned to reflect light emitted by the at least one semiconductor die into a region defining a disc perpendicular to the axis of the LED. Preferably, the dielectric casing has an index of refraction greater than 1.42.

The invention also provides a method of directing light in a light emitting diode (LED) assembly, the method comprising: emitting light from a semiconductor die embedded in a dielectric casing; and reflecting the emitted light from a parabolic surface portion of the dielectric casing. Preferably, the reflecting comprises reflecting the light into a region in the form of a disc perpendicular to the axis of the LED. Preferably, the reflecting comprises reflecting the emitted light from a plurality of the parabolic surface portions.

In another aspect, the invention provides a light emitting diode (LED) assembly having an integral reflector comprising: a dielectric casing of optically transparent material; first and second electrical leads extending within the dielectric casing; and at least one semiconductor die embedded in the dielectric casing and coupled to the first and second leads in a manner allowing for transfer of electrical energy to and illumination of the at least one semiconductor die; wherein the dielectric casing includes an integral concavity substantially opposite the at least the one semiconductor die, the concavity being shaped and dimensioned for reflecting light emitted by the at least one semiconductor die; and, wherein the concavity forms a truncated cone whose surface is described by revolving around the symmetric axis of the LED a parabolic segment defined by the equation y²=2Px, P representing a constant scale factor, the parabolic segment having its focus coincident with the centroid of the at least one semiconductor die and its vertex coincident with a line representing the x-axis passing through the centroid, the angle between the x-axis and the LED axis of symmetry determining the deflection angle of the reflector and being greater than 0° and less than 180°; and, wherein reflection at the parabolic surface occurs by means of total internal reflection according to Snell's Law as expressed by the equation sinθ_{c}=n₁/n₂, θ_{c} representing the critical minimum angle of incidence beyond which a ray striking the parabolic surface will be totaling reflected, n₁ representing the refractive index of air, and n₂ representing the refractive index of the dielectric casing.

In yet another aspect, the invention provides a light emitting diode (LED) assembly having multiple integral reflectors, the assembly comprising: a dielectric casing of optically transparent material; first and second electrical leads extending within the dielectric casing; and at least one semiconductor die embedded in the dielectric casing and coupled to the first and second leads in a manner allowing for transfer of electrical energy to and illumination of the at least one semiconductor die; and, wherein the dielectric casing includes a multiplicity of convex surfaces substantially opposite the at least one semiconductor die, the convex surfaces shaped and dimensioned for reflecting light emitted by the at least one semiconductor die; and, wherein each convex surface has an associated x-axis which passes through the centroid of the at least one semiconductor die; and each convex surface forms a truncated cone as described by revolving around the associated x-axis a parabolic segment defined by the equation y²=2Px, P representing a constant scale factor, the parabolic segment having its focus coincident with the centroid of the at least one semiconductor die and its vertex coincident with the associated x-axis, the angle between the associated x-axis and the LED axis of symmetry determining the deflection angle of the reflector and being greater than 0° and less than 180°; and, wherein reflection at the parabolic surface occurs by means of total internal reflection according to Snell's Law as expressed by the equation sinθ_{c}=n₁/n₂, θ_{c} representing the critical minimum angle of incidence beyond which a ray striking the parabolic surface will be totally reflected, n₁ representing the refractive index of air, and n₂ representing the refractive index of the dielectric casing.

The invention not only provides a compact, simple solution to the problem of directing the light from the LED, but also does so without adding to the size and simplicity of the LED. LEDs according to the invention can be distinguished from conventional LEDs only by the fact that their light is precisely directed. Numerous other advantages and features of the invention will become apparent from the following detailed description when read in conjunction with the drawings.

### BRIEF DESCRIPTION OF THE DRAWINGS

FIG. 1 is an isometric view of a preferred embodiment of the invention;

FIG. 2 is a longitudinal-cross sectional view of the embodiment of FIG. 1 through the line 2-2 in FIG. 1;

FIG. 3 is an isometric view of an alternative preferred embodiment of the invention; and

FIG. 4 is a longitudinal cross-sectional view of the embodiment of FIG. 3 through the line 4-4 in FIG. 3.

### DETAILED DESCRIPTION OF THE INVENTION

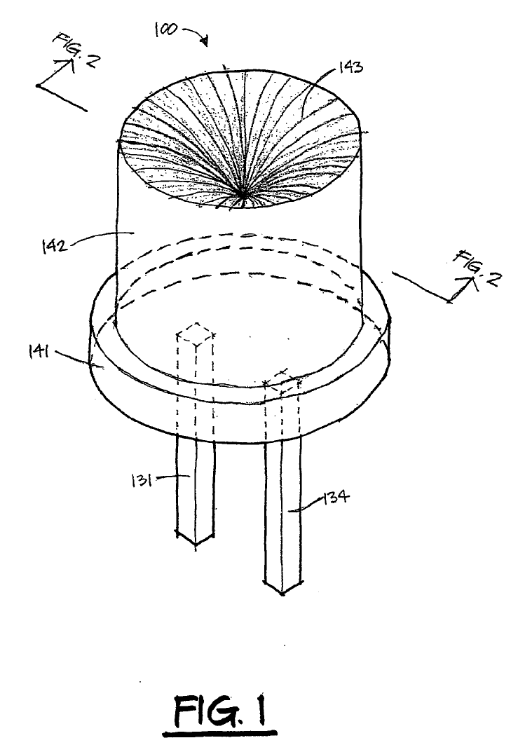

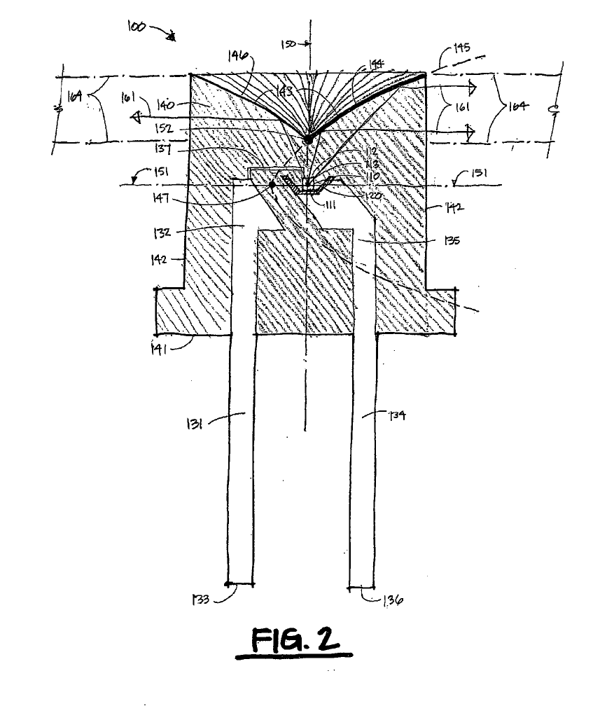

FIG. 1 represents an isometric view of a preferred embodiment of the invention, while FIG. 2 represents a detailed longitudinal section of the invention through the line 2-2 of FIG. 1. LED 100 comprises: semiconductor die 110 which is disposed in die cup 120; anode lead 131 comprising anode lead embedded end 132 and anode lead connection end 133; cathode lead 134 comprising cathode lead embedded end 135 and cathode lead connection end 136; circuit wire 137; and dielectric casing 140. Dielectric casing 140 is an optically clear non-conductive material which encapsulates: semiconductor die 110, die cup 120, anode lead connection end 133; cathode lead embedded end 135; and circuit wire 137. Cathode lead embedded end 135 is electrically connected to die cup 120 which, in turn, is in electrical contact with cathode pole 111 of semiconductor die 110. Anode pole 112 of semiconductor die 110 is in electrical contact with one end of circuit wire 137. The other end of circuit wire 137 is in electrical contact with anode lead embedded end 132.

Dielectric casing 140 is preferably bounded by: flanged bottom 141, cylindrical side 142, and parabolic cone 143. Die cup 120, cylindrical side 142, and parabolic cone 143 are preferably aligned with their axes of symmetry co-linear with LED axis 150. The angle between X-axis 151 and LED axis 150 determines the deflection angle of the reflecting interface 146. In this embodiment, X-axis 151 is perpendicular to LED axis 150 resulting in a deflection angle of 90°. LED axis 150 intersects parabolic cone 143 at conical vertex 152. LED axis 150 intersects X-axis 151 at centroid 113 of semiconductor die 110.

The surface of parabolic cone 143 is described by revolving parabolic curve 144 about LED axis 150. Parabolic curve 144 is a segment of a two-dimensional graph derived from the parabolic equation:

y²=2Px (Equation 1)

as constructed relative to X-axis 151. The focus point of parabolic curve 144 coincides with centroid 113 of semiconductor die 110, and parabolic vertex 147 lies on X-axis 151. The constant P in Equation 1 serves as a scale factor gauging the relative opening width of parabola 145, and in this embodiment P is chosen to be 1.

When an electrical current is applied to anode lead connection end 133 and cathode lead connection end 136, semiconductor die 110 will illuminate; and because semiconductor die 110 is contained within die Cup 120, all radiation is directed toward parabolic cone 143. Because of its small size, semiconductor die 110 can be treated as a point source of light located at the focus of parabolic segment 144, which describes parabolic cone 143. Rays 161 emanating from semiconductor die 110 and striking the surface 146 of parabolic cone 143 are reflected in a direction parallel to X-axis 151 and form, in this embodiment, a light distribution pattern resembling a thin flat disc 164 of rays 161 radiating perpendicular to LED axis 150.

No mirrored coating surface is required for reflection at the surface 146 of parabolic cone 143 because it forms the interface 146 between materials of differing refractive index and, according to Snell's Law, total internal reflection will occur at interface 146 if the incident angle of ray 161 exceeds the critical angle θ_{c} given by the following formula:

sin θ_{c}=n₁/n₂ (Equation 2),

where n₁ is the refractive index of air (˜1.00) and n₂ is the refractive index of dielectric casing 140. Solving for n₂ we get:

n₂=1/sin θ_{c} (Equation 3).

The smallest angle of incidence for ray 161 is 45° when striking near conical vertex 153. Substituting, we find:

n₂=1/sin(45) (Equation 4), and

n₂=1.42 (Equation 5.)

Thus, total internal reflection will occur when the refractive index of dielectric casing 140 exceeds 1.42. Preferably, epoxy resin is employed for this embodiment since it has a refractive index which exceeds 1.50, though other materials with suitable refractive index can be used.

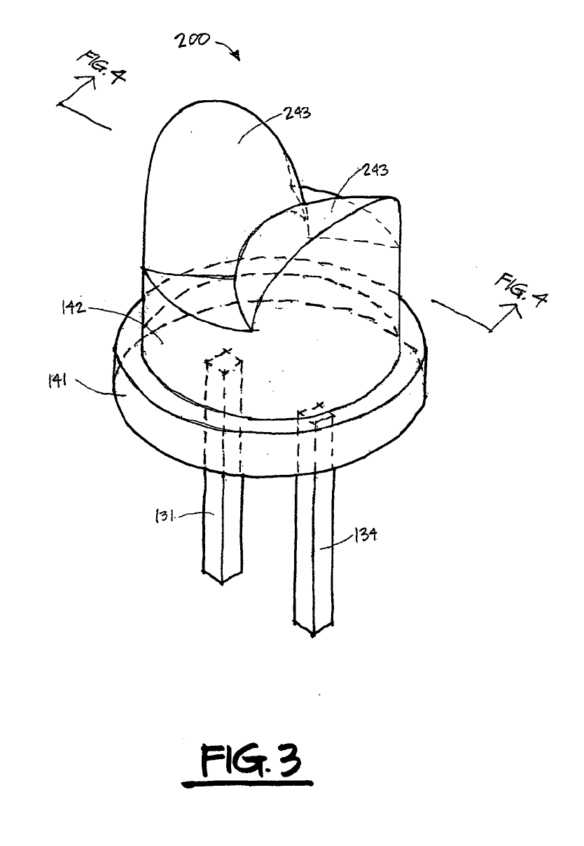

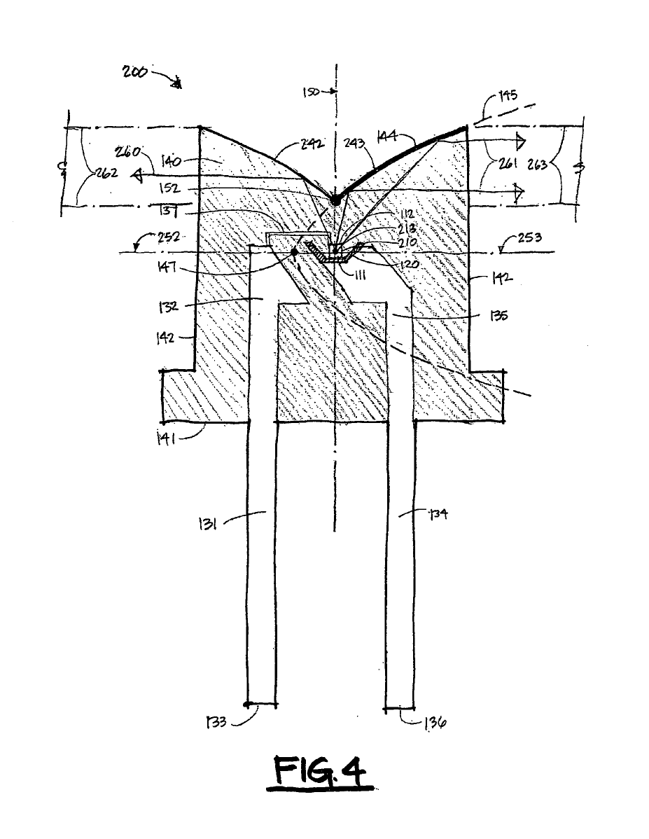

Other embodiments of the invention may include one or more of the following features. Reconfiguration of the parabolic reflecting surface can provide two collimated beams which radiate in separate directions from LED axis 150. FIG. 3 represents an isometric view of such an additional embodiment 200 used, for example, as a beam splitter. FIG. 4 is a detailed longitudinal section through line 4-4 of FIG. 3. Two separate parabolic cones 242 and 243 each are formed by revolving parabolic curve 144 180° around X-axis 252 and X-axis 253, respectively, each of which passes through centroid 213 of semiconductor die 210. Parabolic cones 242 and 243 are mirror images of one another and split light rays 260 and 261 emanating from semiconductor die 210 into two beams 262 and 263 oriented in two separate directions toward the positive end of each associated X-axis 252 and 253.

Alternatively, one parabolic cone or more than two separate parabolic cones, each with an independent X-axis, can be arranged opposite the semiconductor die resulting in the ability to redirect one or a multiplicity of collimated beams oriented at independent deflection angles relative to LED axis 150.

In its various configurations, the invention discloses an LED with a compact integral parabolic reflector system which allows multi-directional light radiating from the semiconductor die to be precisely collimated and directed at significant angles away from the LED's axis of symmetry in useful planar and beam-shaped patterns. Examples of devices which could beneficially employ the invention include, but are not limited to, the following: edge-lit panels for instrumentation; beam splitters for fiber optic systems; planar illumination fixtures; and compact lighting devices.

There has been described a novel LED having an integral parabolic reflector. It should be understood that the specific formulations and methods described herein are exemplary and should not be construed to limit the invention, which will be described in the claims below. Further, it is evident that those skilled in the art may now make numerous uses and modifications of the specific embodiments described without departing from the inventive concepts. For example, coatings may be applied to the reflective surface to enhance the reflection; or in some embodiments, all or a portion of the reflecting parabolic surface may be formed by a silvered coating or layer. Consequently, the invention is to be construed as embracing each and every novel feature and novel combination of features present in and/or possessed by the compositions and methods described and by their equivalents.

What is claimed as new and desired to be protected by Letters Patent of the United States is:

1-12. (canceled)

13. A light emitting diode (LED) assembly comprising:
a dielectric casing of optically transparent material;
first and second electrical leads extending within said dielectric casing;
at least one semiconductor die embedded in said dielectric casing and coupled to said first and second leads in a manner allowing for transfer of electrical energy to and illumination of said at least one semiconductor die; and
wherein said dielectric casing has a surface, at least a portion of which is parabolic, said parabolic surface portion located and dimensioned for reflecting light emitted by said at least one semiconductor die, wherein said parabolic surface portion defines a parabolic curve rotated around an axis through said LED and perpendicular to the axis of said LED.

14. An LED assembly as in claim 13 wherein said parabolic surface portion defines a parabolic curve rotated around an axis through said LED and perpendicular to the axis of said LED.

15. An LED assembly as in claim 13 wherein the parabolic surface portion provides two collimated beams which radiate in separate directions.

16. An LED assembly as in claim 13 wherein the parabolic surface portion has two separate parabolic cones.

17. An LED assembly as in claim 16 wherein the two separate parabolic cones are formed by revolving a parabolic curve 180° around a first X-axis and a second X-axis, respectively, each of which passes through a centroid of the at least one semiconductor die.

18. An LED assembly as in claim 13 wherein at least two separate parabolic cones, each with an independent X-axis, are arranged opposite the semiconductor die redirecting a multiplicity of collimated beams oriented at independent deflection angles relative to an LED axis.

19. A method of directing light in a light emitting diode (LED) assembly, said method comprising:
emitting light from a semiconductor die embedded in a dielectric casing; and
reflecting said emitted light from a parabolic surface portion of said dielectric casing, wherein said reflecting comprises reflecting said emitted light from a plurality of said parabolic surface portions.

20. An LED assembly as in claim 19 wherein the plurality of said parabolic surface portions provides two collimated beams which radiate in separate directions.

21. A light emitting diode (LED) assembly having multiple integral reflectors, said assembly comprising:
a dielectric casing of optically transparent material;
first and second electrical leads extending within said dielectric casing; and
at least one semiconductor die embedded in said dielectric casing and coupled to said first and second leads in a manner allowing for transfer of electrical energy to and illumination of said at least one semiconductor die;
wherein said dielectric casing includes a multiplicity of convex surfaces substantially opposite said at least one semiconductor die, the convex surfaces shaped and dimensioned for reflecting light emitted by said at least one semiconductor die;
wherein each said convex surface has an associated X-axis which passes through the centroid of said at least one semiconductor die; and each said convex surface forms a truncated cone as described by revolving around said associated X-axis a parabolic segment defined by the equation y²=2Px, P representing a constant scale factor, said parabolic segment having its focus coincident with the centroid of said at least one semiconductor die and its vertex coincident with said associated X-axis, the angle between said associated X-axis and the LED axis of symmetry determining the deflection angle of the reflector and being greater than 0° and less than 180°; and
wherein reflection at said parabolic surface occurs by means of total internal reflection according to Snell's Law as expressed by the equation sinθ_{c}=n₁/n₂, θ_{c} representing the critical minimum angle of incidence beyond which a ray striking the parabolic surface will be totally reflected, n₁ representing the refractive index of air, and n₂ representing the refractive index of said dielectric casing.

22. A light emitting diode (LED) assembly as in claim 21 wherein the convex surfaces provide two collimated beams which radiate in separate directions.
